(19) United States
(12) Patent Application Publication
(10) Pub. No.: US 2015/0093863 A1
(43) Pub. Date: Apr. 2, 2015

(54) METHOD OF MAKING A FLOATING GATE NON-VOLATILE MEMORY (NVM) WITH BREAKDOWN PREVENTION

(71) Applicant: ANIRBAN ROY, Austin, TX (US)

(72) Inventor: ANIRBAN ROY, Austin, TX (US)

(21) Appl. No.: 14/041,449

(22) Filed: Sep. 30, 2013

(51) Int. Cl. H01L 21/28; H01L 27/115

(52) U.S. Cl. CPC H01L 21/28273; H01L 27/11521
USPC 438/211

(57) ABSTRACT

A method of making a semiconductor structure includes patterning a polysilicon layer on a substrate to form a first floating gate over a first active region in the substrate and a second floating gate over a second active region in the substrate. An opening between the first and second floating gates is filled with a dielectric material. The dielectric material is etched back so that a height of a remaining portion of the dielectric material is less than a height of the first and second floating gates. A second polysilicon layer is deposited over the first and second floating gates and the remaining portion of the dielectric material to form a word line for the first and second floating gates.

### BACKGROUND

1. Field

This disclosure relates generally to non-volatile memories (NVM) and more particularly to NVMs that use floating gate charge storage.

2. Related Art

In a typical floating gate NVM, a control gate extends over multiple floating and functions as a word line. As the NVM cell scale to smaller dimensions, the floating gate becomes smaller and the control gate then is closer to the active region. Due to the relatively high voltages required for program and erase operations, the voltage requirements may not scale in the same proportion as the size reductions. Thus, breakdown between control gate and the active region can become a bigger problem with dimension scaling. Avoiding this problem can result in complicated processes that are costly.

Accordingly there is a need to provide a method that improves upon one or more of the issues raised above.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of an NVM structure according to an embodiment;

FIG. 2 is a cross section of the NVM structure of FIG. 1 at a subsequent stage in processing;

FIG. 3 is a cross section of the NVM structure of FIG. 2 at a subsequent stage in processing;

FIG. 4 is a cross section of the NVM structure of FIG. 3 at a subsequent stage in processing;

FIG. 5 is a cross section of the NVM structure of FIG. 4 at a subsequent stage in processing;

FIG. 6 is a cross section of the NVM structure of FIG. 5 at a subsequent stage in processing;

FIG. 7 is a cross section of the NVM structure of FIG. 6 at a subsequent stage in processing;

FIG. 8 is a cross section of the NVM structure of FIG. 7 at a subsequent stage in processing;

FIG. 9 is a simplified top view of the NVM structure of FIG. 8;

FIG. 10 is a simplified top view of the NVM structure of FIG. 9 at a subsequent stage in processing; and

FIG. 11 is a simplified top view of the NVM structure of FIG. 10 at a subsequent stage in processing.

### DETAILED DESCRIPTION

In one aspect, a method of making a floating gate non-volatile memory (NVM) structure achieves floating gate structures by a patterned etch that results in the floating gate structures each extending just over corresponding active regions. In the word line direction, a dielectric fill is formed between adjacent floating gate structures. The dielectric fill is etched back between the adjacent floating gate structures to a desired level above the bottom surfaces of the floating gate structures. An inter-gate dielectric for use between control gate and floating gate is formed over the floating gate structures. Control gate material is formed over the inter-gate dielectric. The control gate material and the floating gate structures are etched to form word lines of control gate material in which each word line is over a plurality of floating gates in the word line direction. This is better understood by reference to the drawings and the following written description.

The semiconductor substrate described herein can be any semiconductor material or combinations of materials, such as gallium arsenide, silicon germanium, silicon-on-insulator (SOI), silicon, monocrystalline silicon, the like, and combinations of the above. Oxide layer refers to a silicon oxide layer unless otherwise noted. Similarly, nitride layer refers to a silicon nitride layer unless otherwise noted.

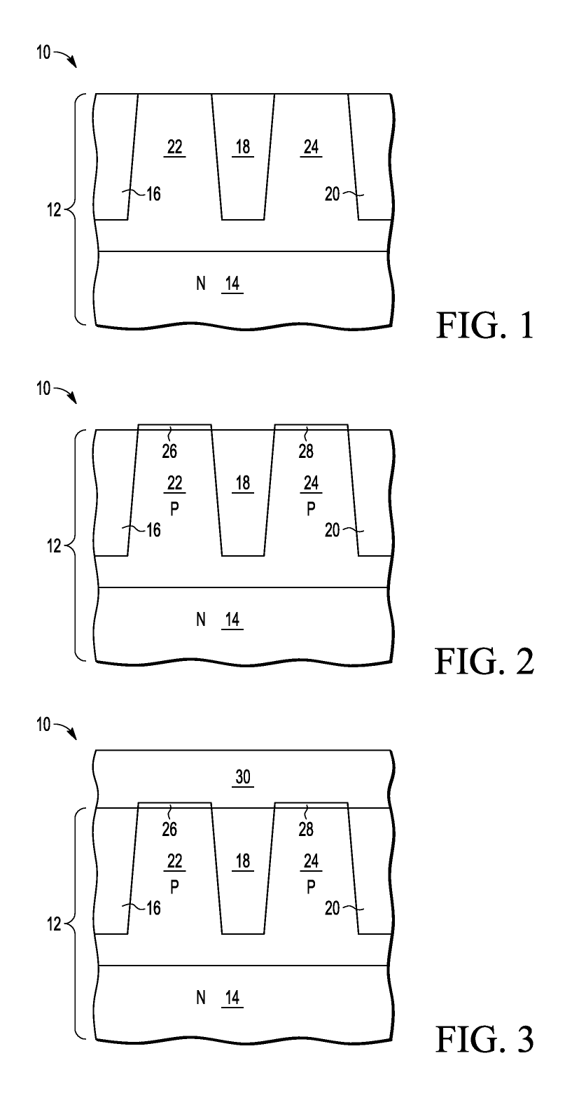

Shown in FIG. 1 is a non-volatile memory (NVM) structure 10 circuit having a substrate 12, a barrier layer 14 in substrate 12 that is N-type, isolation regions 16, 18, and 20, a well 22 in substrate 12 above barrier layer 14 and between isolation regions 16 and 18, and a well 24 in substrate 12 above barrier layer 14 and between isolation regions 18 and 20. Wells 22 and 24 may be P-type. Wells 22 and 24 are active regions that have a particular doping, in this case P-type of a concentration that is selected for the type of transistors to be formed in the wells. Thus well 22 may also considered active region 22, and well 24 may be considered active region 24.

Shown in FIG. 2 is NVM structure 10 after forming a gate dielectric 26 on well 22 and a gate dielectric 28 on well 24. Gate dielectrics 26 and 28 may be formed by growing oxide at relatively high temperature such as 900 degrees Celsius for the case of substrate 12 being silicon. A different gate dielectric may be used instead.

Shown in FIG. 3 is NVM structure 10 after forming a layer 30 of floating gate material such as polysilicon over gate dielectrics 26 and 28 and isolation regions 16, 18, and 20.

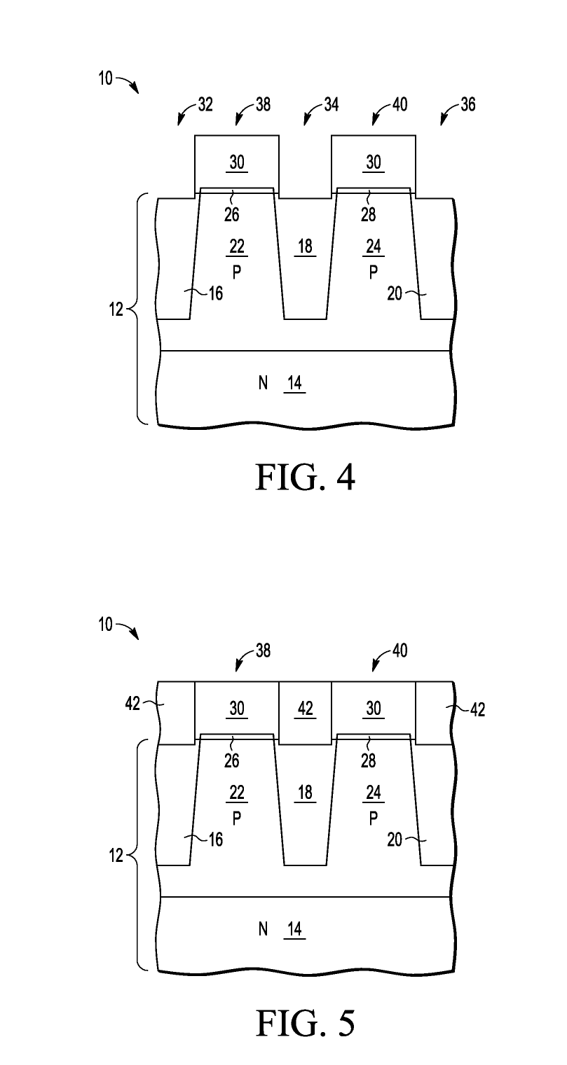

Shown in FIG. 4 is NVM structure 10 patterning layer 30 that results in openings 32, 34, and 36 with a floating gate structure 38 between openings 32 and 34 and a floating gate structure 40 between openings 34 and 36. In the word line direction, layer 30 is discontinuous with multiple floating gate structures such as floating structures 38 and 40. In the bit line direction, floating gate structures 38 and 40 extend continuously in the bit line direction.

Shown in FIG. 5 is NVM structure 10 after depositing a layer 42 of dielectric material such as oxide and performing chemical mechanical polishing to result in layer 42 being in openings 32, 34, and 36 and layer 42 having a top surface that is coplanar with the top surface of layer 30 and thus the top surface of floating gate structures 38 and 40.

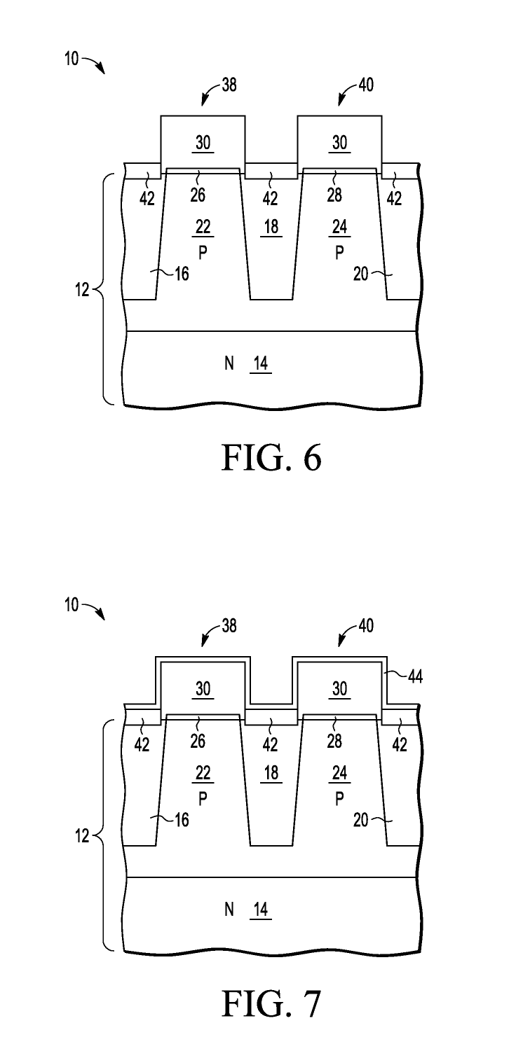

Shown in FIG. 6 is NVM structure 10 after etching back layer 42 to a height that is above a bottom surface of floating structures 38 and 40. The height above the bottom surfaces of floating gate structures 38 and 40 is chosen based on the desired breakdown between a control gate and the wells such as wells 22 and 24. Isolation regions 16, 18, and 20 are recessed resulting from the etch that formed openings 32, 34, and 36. Thus the desired height of resulting layer 42 as shown in FIG. 6 must take into account this recess. Gate dielectrics 26 and 28 may also be a factor to consider. A height of at least 10 nanometers is expected to be effective.

Shown in FIG. 7 is NVM structure 10 forming an inter-gate dielectric 44 over layer 42, on exposed sidewalls of floating gate structures 38 and 40, and on the top surface of floating gate structures 38 and 40. Inter-gate dielectric 44 may be stack of two oxide layers with a nitride layer between the two oxide layers.

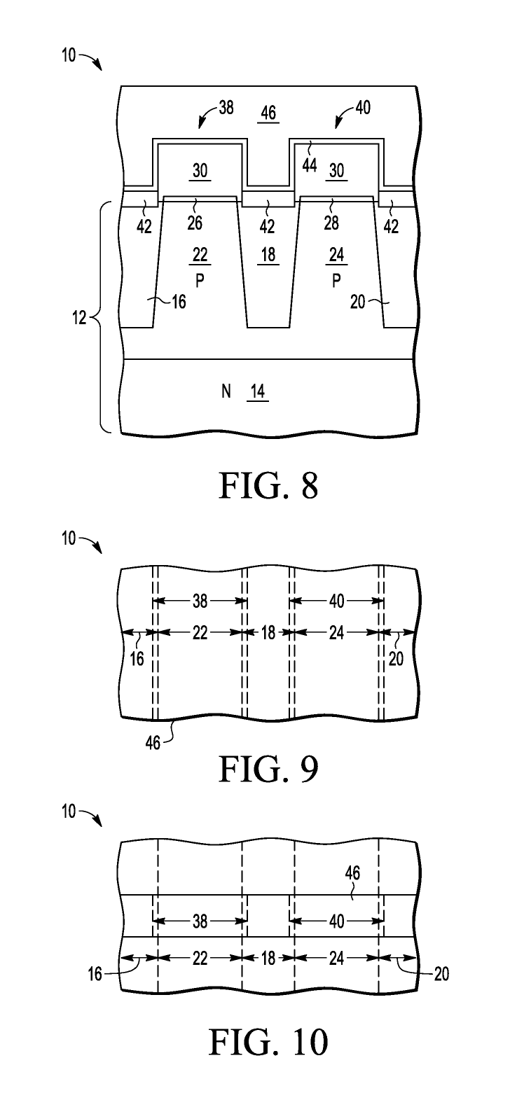

Shown in FIG. 8 is NVM structure 10 after forming a layer 46 of a material suitable for a control gate. This material may be polysilicon that is doped. This doping may be in situ or by implant. An etch of layer 46, layer 44, and layer 30 using the same mask will result in an NVM gate stack having a floating gate, an inter-gate dielectric, and a control gate. The gate stack is then used, potentially in combination with one or more sidewall spacers in forming source/drain regions. Neither the result of the etch nor the source/drain will show up in the cross section of FIG. 8

Shown in FIG. 9 is NVM structure 10, in a simplified top view, is NVM structure 10 with layer 46 covering NVM structure 10, floating gate structures 38 and 40 shown as bounded by dotted lines, isolation region 18 bounded by dotted lines, wells 22 and 24 bounded by dotted lines, isolation region 16 bounded by one edge of FIG. 9 and a dotted line, and isolation region 20 bounded by an opposing edge of FIG. 9 and a dotted line.

Shown in FIG. 10 is NVM structure 10 after pattern-etching layer 46, inter-gate dielectric 44, and floating gate structures 38 and 40 according to the same pattern so that edges of these three layers are self-aligned. Patterned layer 46, being on top, is shown running in the word line direction floating gate structures 38 and 40, having been etched so that each remaining portion is a floating gate for a single NVM cell. In the word line direction, multiple floating gates are under patterned layer 46, which is a word line of the larger NVM not fully shown. Patterned layer 46, considered a word line, may also be strapped to an overlying metal line that may also be considered a word line.

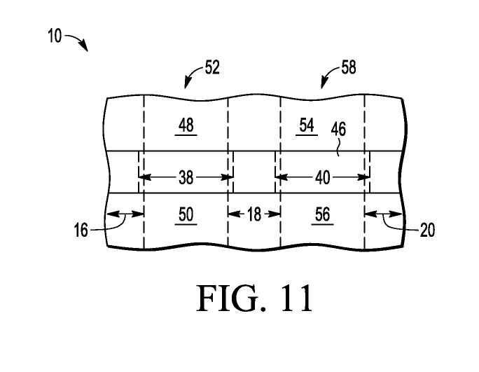

Shown in FIG. 11 is NVM structure 10 after forming source/drains 48 and 50 in well 22 resulting in an NVM cell 52 and forming source/drains 54 and 56 in well 24 resulting in NVM cell 58. Source/drains 48, 50, 54, and 56 may be formed by implant. In addition to the gate stacks being used as an implant mask, there may be formed sidewall spacers and liners that are also used as implant masks for the implant or implants that form source/drains 48, 50, 54, and 56.

Thus it is shown that an NVM cell can be formed that results in a controlled distance from its corresponding active region such as wells 22 and 24 by a method that is simple and cost effective.

By now it should be apparent that there has been shown a method of making a semiconductor structure. The method includes patterning a polysilicon layer on a substrate to form a first floating gate over a first active region in the substrate and a second floating gate over a second active region in the substrate. The method includes filling an opening between the first and second floating gates with a dielectric material. The method includes etching back the dielectric material so that a height of a remaining portion of the dielectric material is less than a height of the first and second floating gates. The method includes depositing a second polysilicon layer over the first and second floating gates and the remaining portion of the dielectric material to form a word line for the first and second floating gates. The method may further include depositing an interlayer dielectric over the first and second floating gates and the remaining portion of the dielectric material before depositing the second polysilicon layer. The method may have a further characterization by which the first and second active regions are one of: a P-well and an N-well. The method may further include forming an isolation region between the first and second active regions, wherein the remaining portion of the dielectric material is over the isolation region. The method may have a further characterization by which the interlayer dielectric includes a layer of nitride material between two layers of oxide material. The method may further include growing a layer of gate oxide over the first and second active regions on the substrate before patterning the first and second floating gates. The method may further include forming a buried well region in the substrate under the first and second active regions.

Also disclosed is a method of making a semiconductor structure. The method includes patterning polysilicon to form a first floating gate over a first active region in a semiconductor substrate. The method includes patterning the polysilicon to form a second floating gate over a second active region in the semiconductor substrate. The method includes depositing a dielectric material over an isolation region between the first and second active regions. The method includes etching back the dielectric material so that a top surface of a remaining portion of the dielectric material is above a bottom surface of the first and second floating gates. The method includes depositing a second polysilicon in an opening above the remaining portion of the dielectric material to form a word line for the first and second floating gates. The method may further include lining the opening above the remaining portion of the dielectric material with an interlayer dielectric. The method may have a further characterization by which the interlayer dielectric includes a layer of nitride material between first and second layers of oxide material. The method may further include forming a buried well under the first and second active regions. The method may have a further characterization by which the first active region is one of a group consisting of a P-well and an N-well. The method may have a further characterization by which the isolation region is a shallow trench isolation region. The method may have a further characterization by which a distance between the top surface of the remaining portion of the dielectric material is at least 10 to 15 nanometers above the bottom surface of the first and second floating gates.

Disclosed also is a method of making a semiconductor structure. The method includes forming a first floating gate over a first active region in a substrate. The method includes forming a second floating gate over a second active region in the substrate. The method includes forming an isolation region between the first and second active regions, wherein corners of a bottom surface of the first and second floating gates extend over side edges of the isolation region. The method includes depositing a dielectric material in an opening over the isolation region between the first and second floating gates. The method includes removing a portion of the dielectric material in the opening so that a remaining portion of the dielectric material is below a top of the opening. The method includes depositing polysilicon in the opening to form a word line for the first and second floating gates. The method may have a further characterization by which a height of a top surface of side edges of the isolation region is greater than a height of a top surface of an inner portion of the isolation region. The method may further include depositing an interlayer dielectric over the first and second floating gates and the remaining portion of the dielectric material before depositing the polysilicon to form the word line. The method may have a further characterization by which the first and second active regions are one of: a P-well and an N-well. The method may have a further characterization by which the interlayer dielectric includes a layer of nitride material between two layers of oxide material. The method may further include growing a layer of gate oxide over the first and second active regions on the substrate before patterning the first and second floating gates and forming a buried well region in the substrate under the first and second active regions.

Although the invention is described herein with reference to specific embodiments, various modifications and changes can be made without departing from the scope of the present invention as set forth in the claims below. For example, different materials may be used and thicknesses may be chosen by experimentation based on the particular processes that are being used. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method of making a semiconductor structure, comprising:
patterning a polysilicon layer on a substrate to form a first floating gate over a first active region in the substrate and a second floating gate over a second active region in the substrate;
filling an opening between the first and second floating gates with a dielectric material;
etching back the dielectric material so that a height of a remaining portion of the dielectric material is less than a height of the first and second floating gates; and
depositing a second polysilicon layer over the first and second floating gates and the remaining portion of the dielectric material to form a word line for the first and second floating gates.

2. The method of claim 1 further comprising depositing an interlayer dielectric over the first and second floating gates and the remaining portion of the dielectric material before depositing the second polysilicon layer.

3. The method of claim 1, wherein the first and second active regions are one of: a P-well and an N-well.

4. The method of claim 1, further comprising forming an isolation region between the first and second active regions, wherein the remaining portion of the dielectric material is over the isolation region.

5. The method of claim 2, wherein the interlayer dielectric includes a layer of nitride material between two layers of oxide material.

6. The method of claim 1, further comprising growing a layer of gate oxide over the first and second active regions on the substrate before patterning the first and second floating gates.

7. The method of claim 1, further comprising forming a buried well region in the substrate under the first and second active regions.

8. A method of making a semiconductor structure comprising:
patterning polysilicon to form a first floating gate over a first active region in a semiconductor substrate;
patterning the polysilicon to form a second floating gate over a second active region in the semiconductor substrate;
depositing a dielectric material over an isolation region between the first and second active regions;
etching back the dielectric material so that a top surface of a remaining portion of the dielectric material is above a bottom surface of the first and second floating gates; and
depositing a second polysilicon in an opening above the remaining portion of the dielectric material to form a word line for the first and second floating gates.

9. The method of claim 8, further comprising lining the opening above the remaining portion of the dielectric material with an interlayer dielectric.

10. The method of claim 9, wherein the interlayer dielectric includes a layer of nitride material between first and second layers of oxide material.

11. The method of claim 8, further comprising forming a buried well under the first and second active regions.

12. The method of claim 8, wherein the first active region is one of a group consisting of a P-well and an N-well.

13. The method of claim 12 wherein the isolation region is a shallow trench isolation region.

14. The method of claim 12 wherein a distance between the top surface of the remaining portion of the dielectric material is at least 10 to 15 nanometers above the bottom surface of the first and second floating gates.

15. A method of making a semiconductor structure comprising:
forming a first floating gate over a first active region in a substrate;
forming a second floating gate over a second active region in the substrate;
forming an isolation region between the first and second active regions, wherein corners of a bottom surface of the first and second floating gates extend over side edges of the isolation region;
depositing a dielectric material in an opening over the isolation region between the first and second floating gates;
removing a portion of the dielectric material in the opening so that a remaining portion of the dielectric material is below a top of the opening; and
depositing polysilicon in the opening to form a word line for the first and second floating gates.

16. The method of claim 15, wherein a height of a top surface of side edges of the isolation region is greater than a height of a top surface of an inner portion of the isolation region.

17. The method of claim 15 further comprising depositing an interlayer dielectric over the first and second floating gates and the remaining portion of the dielectric material before depositing the polysilicon to form the word line.

18. The method of claim 15, wherein the first and second active regions are one of: a P-well and an N-well.

19. The method of claim 17, wherein the interlayer dielectric includes a layer of nitride material between two layers of oxide material.

20. The method of claim 1, further comprising:
growing a layer of gate oxide over the first and second active regions on the substrate before patterning the first and second floating gates; and
forming a buried well region in the substrate under the first and second active regions.
